(19) United States
(12) Patent Application Publication
(10) Pub. No.: US 2010/0144137 A1
(43) Pub. Date: Jun. 10, 2010

(54) METHOD OF INTERCONNECTING CHIPS USING CAPILLARY MOTION

(75) Inventors: Kwang-yong LEE, Anyang-si (KR); Jong-gi Lee, Yongin-si (KR); Min-ill Kim, Cheonan-si (KR); Min-seung Yoon, Seoul (KR); Ji-seok Hong, Seoul (KR)

Correspondence Address: STANZIONE & KIM, LLP, 919 18TH STREET, N.W., SUITE 440, WASHINGTON, DC, 20006, US

(73) Assignee: Samsung Electronics Co., Ltd, Suwon-si (KR)

(21) Appl. No.: 12/579,483

(22) Filed: Oct. 15, 2009

(30) Foreign Application Priority Data
Dec. 8, 2008 (KR) 10-2008-0124301

(51) Int. Cl. H01L 21/768

(52) U.S. Cl. 438/618; 257/E21.588

(57) ABSTRACT

A method of interconnecting semiconductor devices by using capillary motion, thereby simplifying fabricating operations, reducing fabricating costs, and simultaneously filling of through-silicon-vias (TSVs) and interconnecting semiconductor devices. The method includes preparing a first semiconductor device in which first TSVs are formed, positioning solder balls respectively on the first TSVs, performing a back-lap operation on the first semiconductor device, positioning a second semiconductor device, in which second TSVs are formed, above the first semiconductor device on which the solder balls are positioned, and performing a reflow operation such that the solder balls fill the first and second TSVs due to capillary motion.

### CROSS-REFERENCE TO RELATED APPLICATIONS

This application claims the benefit of Korean Patent Application No. 10-2008-0124301, filed on Dec. 8, 2008, in the Korean Intellectual Property Office, the disclosure of which is incorporated herein in its entirety by reference.

### BACKGROUND

1. Field of the Invention

The present general inventive concept relates to a method of fabricating a semiconductor device, and more particularly, to a method of vertically interconnecting semiconductor devices by using a through-silicon-via (TSV) formed in the semiconductor devices.

2. Description of the Related Art

In conventional semiconductor systems, a general method of improving integration of a semiconductor device is by making a design rule finer and arranging internal components, such as transistors, capacitors, etc., three-dimensionally to include more integrated circuits within a small area during fabrication of a wafer. However, a currently used method of improving integration of a semiconductor device is vertically stacking semiconductor chips with smaller thicknesses to include more semiconductor chips within a single semiconductor package. Such a method of improving integration of a semiconductor memory device is advantageous in terms of costs, time for research and development, and the realization of manufacturing operations. Thus, related researches are being actively conducted on such a method of improving integration of a semiconductor memory device.

However, various techniques may be applied for vertically interconnecting the semiconductor chips in the case of vertically stacking the semiconductor chips. As such, a method of interconnecting semiconductor chips by using wires is the general method used in the conventional art. However, a method of interconnecting semiconductor chips by forming TSVs in semiconductor chips, forming through electrodes within the TSVs, and interconnecting the semiconductor chips by using the through electrodes has recently been introduced.

### SUMMARY

The present general inventive concept provides a method of interconnecting semiconductor devices by using capillary motion, thereby simplifying fabricating operations, reducing fabricating costs, and simultaneously filling of through-silicon-vias (TSV) and interconnecting semiconductor devices.

Additional aspects and utilities of the present general inventive concept will be set forth in part in the description which follows and, in part, will be obvious from the description, or may be learned by practice of the general inventive concept.

Exemplary embodiments of the present general inventive concept provide a method of interconnecting semiconductor devices by using capillary motion, the method including preparing a first semiconductor device in which first through-silicon-vias (TSV) are formed, positioning conductive bumps respectively on the first TSVs, performing a back-lap operation on the first semiconductor device, positioning a second semiconductor device, in which second TSVs are formed, above the first semiconductor device on which the conductive bumps are positioned respectively on the first TSVs, and performing a reflow operation such that the conductive bumps fill the first and second TSVs due to capillary motion.

The first and second semiconductor devices may be semiconductor chips or wafers.

A seed layer may be formed in each of the first and second TSVs.

The seed layer may include a single-layer structure or a multi-layer structure formed of metals that can easily be combined with solder, metals such as Ti (titanium), Cu (copper), Ni (nickel), and Au (gold).

The seed layer may either be formed only on an inner sidewall of each of the first and second TSVs, or be formed on an inner sidewall and partially on top and bottom surfaces of each of the first and second TSVs.

The method may further include positioning the conductive bumps on the first TSVs and performing a first reflow operation to fix the conductive bumps to the first TSVs. Here, the first reflow operation may be performed at a temperature from 230° C. to 250° C. for a time duration from about 5 seconds to about 15 seconds.

Exemplary embodiments of the present general inventive concept also provide a method of interconnecting semiconductor devices by using capillary motion, the method including preparing a first semiconductor device on which a back-lap operation is performed and in which first through-silicon-vias (TSVs) are formed, positioning solder balls respectively on the first TSVs, positioning a second semiconductor device, in which second TSVs are formed, above the first semiconductor device on which the solder balls are positioned, and performing a reflow operation such that the solder balls fill the first and second TSVs due to capillary motion.

Exemplary embodiments of the present general inventive concept also provide a method of interconnecting semiconductor devices by using capillary motion, the method including aligning through-silicon-vias (TSVs) of at least two semiconductor devices in which back-lap operations have been formed, and performing a reflow operation such that solder balls disposed between each of the respectively aligned TSVs fill the TSVs via capillary motion.

A seed layer is formed in each of the TSVs before the aligning thereof.

The solder balls can be disposed at the TSVs of every other semiconductor device and fixed thereto via a partial reflow operation prior to the reflow operation.

### BRIEF DESCRIPTION OF THE DRAWINGS

Exemplary embodiments of the present general inventive concept will be more clearly understood from the following detailed description taken in conjunction with the accompanying drawings in which:

FIGS. 1 through 5 are sectional views illustrating a method of interconnecting semiconductor devices using capillary motion, according to an embodiment of the present inventive concept;

FIGS. 6 through 10 are sectional views illustrating a method of interconnecting semiconductor devices using capillary motion, according to another embodiment of the present inventive concept; and

FIGS. 11 through 14 are sectional views illustrating a method of interconnecting semiconductor devices using capillary motion, according to another embodiment of the present inventive concept.

### DETAILED DESCRIPTION OF THE EMBODIMENTS

The present inventive concept will now be described more fully with reference to the accompanying drawings, in which exemplary embodiments of the inventive concept are shown. The inventive concept may, however, be embodied in many different forms and should not be construed as being limited to the embodiments set forth herein; rather, these embodiments are provided so that this disclosure will be thorough and complete, and will fully convey the concept of the inventive concept to those of ordinary skill in the art. For example, an embodiment below describes the simultaneous performance of an operation of forming a contact electrode for two semiconductor chips and an operation of interconnecting the two semiconductor chips. However, the embodiment may also be applied to more than two semiconductor chips.

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

FIGS. 1 through 5 are sectional views illustrating a method of interconnecting semiconductor devices using capillary motion, according to an embodiment of the present inventive concept.

Referring to FIGS. 1 through 5, a first semiconductor device 100 on which a predetermined integrated circuit pattern (not shown) is formed is prepared. First through-silicon-vias (TSVs) 102 may be formed in the first semiconductor device 100, and a seed layer 104 may be formed in the first TSV 102.

The first semiconductor device 100 may be either a wafer or a unitary semiconductor chip separated from a wafer. The depth of a first TSV 102 may be from 20 μm to 100 μm, and the diameter of the first TSV 102 may be from 10 μm to 30 μm.

Furthermore, the seed layer 104 may have either a single-layer structure or a multi-layer structure formed of metals which can easily be combined with solder, for example, metals such as titanium (Ti), copper (Cu), nickel (Ni), and gold (Au). The seed layer 104 may be formed to cover the inner sidewall and the bottom surface of the first TSV 102 and to partially cover the top surface of the first semiconductor device 100. The thickness of the seed layer 104 may be from 0.1 μm to 1 μm.

Next, as illustrated in FIG. 3, a solder ball 106 is positioned on the first TSV 102 using a general method. Also, a method of interconnecting semiconductor devices by using capillary motion according to an exemplary embodiment of the present inventive concept may selectively include a first reflow operation on the solder ball 106. Therefore, the solder ball 106 may be fixed at the entrance of the first TSV 102 by performing the first reflow operation. At this point, the first reflow operation may be performed at a temperature from about 230° C. to about 250° C., which is the range of temperatures at which the solder ball 106 begins to melt, for a time duration from about 5 seconds to about 15 seconds.

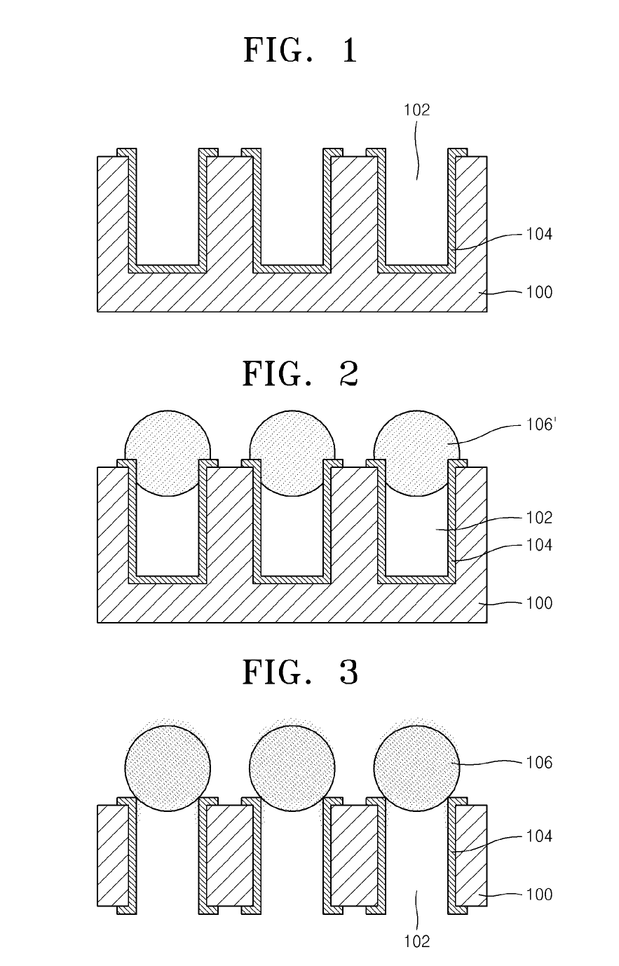

Next, a back-lap operation to polish the bottom surface of the first semiconductor device 100 until the first semiconductor device 100 has a predetermined thickness is performed. Thus, the first TSV 102 completely penetrates the first semiconductor device 100. In case the seed layer 104 is not exposed through the bottom surface of the first semiconductor device 100 after the back-lap operation, an operation of forming a seed layer 104 on the bottom surface of the first semiconductor device 100 may be additionally performed. Alternatively, the seed layer 104 may not be formed on the bottom surface of the first semiconductor device 100. While FIG. 2 illustrates that the first reflow operation is performed on the solder ball 106′, FIG. 3 illustrates the solder ball 106 in a case where the first reflow operation is not performed.

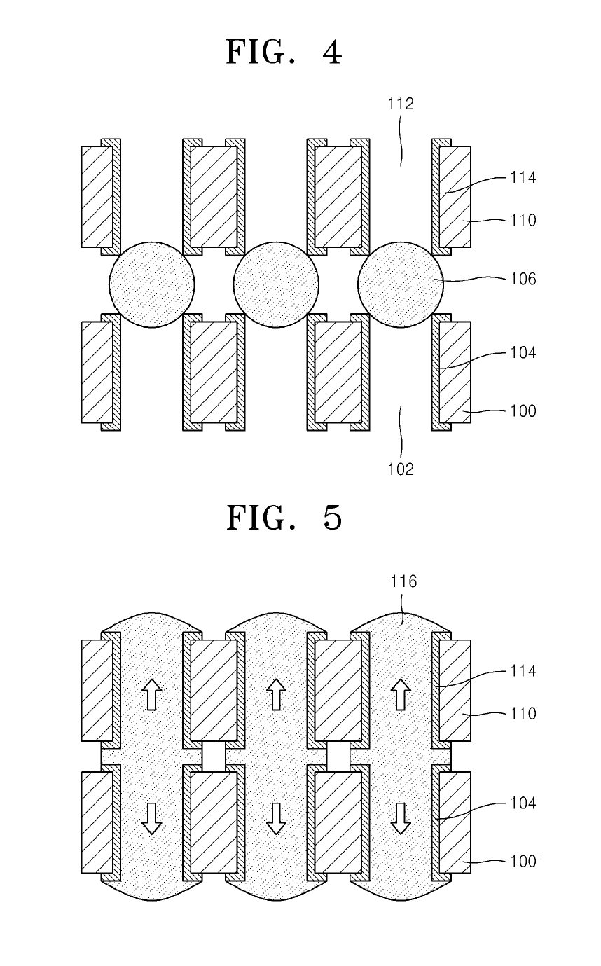

Next, as illustrated in FIG. 4, a second semiconductor device 110 in which second TSVs 112 are formed is positioned above the first semiconductor device 100 in which the solder balls 106 are positioned on the first TSVs 102. The back-lap operation may be previously performed on the second semiconductor device 110 such that the second TSVs 112 completely penetrate the second semiconductor device 110. A seed layer 114 may also have been partially formed on the sidewall of the second semiconductor device 110. The second semiconductor device 110 may be either a semiconductor device performing the same functions as the first semiconductor device 100 or a semiconductor device performing different functions to those of the first semiconductor device 100.

Finally, a second reflow operation is performed on the stacked structure illustrated in FIG. 4 to melt the solder ball 106. At this point, due to capillary motion, the solder ball 106 fills the first TSVs 102 downward and fills the second TSVs 112 upward simultaneously. Therefore, due to capillary motion of the solder ball 106, the formation of a contact electrode 116 and interconnection of the first and second semiconductor devices 100 and 110 are simultaneously performed.

At this point, the solder ball 106 fills the first and second TSVs 102 and 112 in the first and second semiconductor devices 100 and 110, respectively, due to not only capillary motion, but also coherence between the surfaces of the seed layers 104 and 114 and melted solder. Therefore, solder melted through the second reflow operation has excellent coherence with respect to the seed layers 104 and 114 respectively formed in the first and second TSVs 102 and 112, and thus, the solder stays on the seed layers 104 and 114 only. Meanwhile, a gap in the interface between the first and second semiconductor devices 100 and 110 may be selectively filled by using a liquid adhesive as an underfiller.

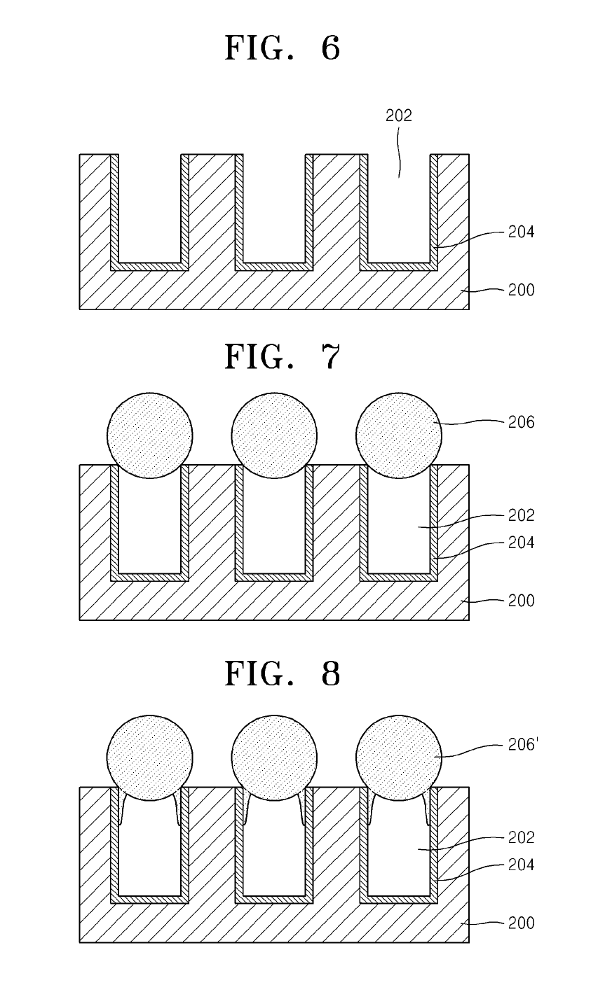

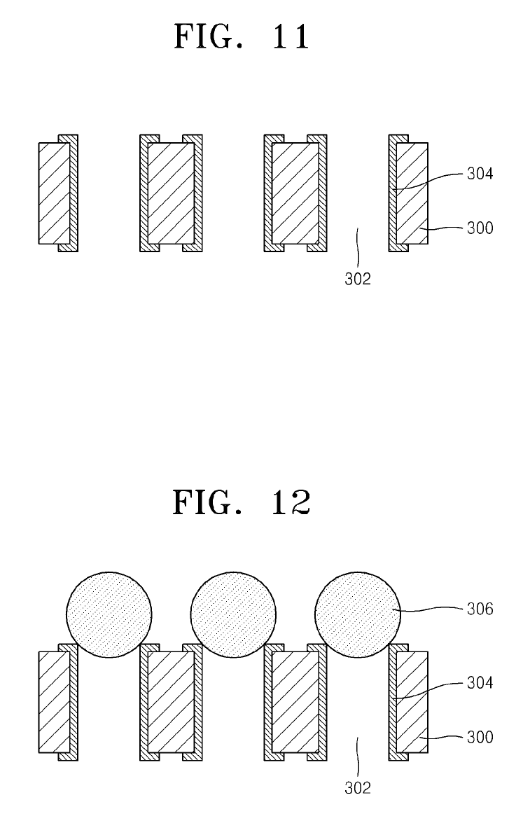

FIGS. 6 through 10 are sectional views illustrating a method of interconnecting semiconductor devices using capillary motion, according to another embodiment of the present inventive concept.

Referring to FIGS. 1 through 5, the seed layer 104 formed in the first TSV 102 covers the inner sidewall and the bottom surface of the first TSV 102 and partially covers the top surface of the first semiconductor device 100 in the embodiment shown in FIGS. 1 through 5. In contrast, the seed layer only covers the inner sidewall of the first TSV in the current embodiment of FIGS. 6 through 10.

More particularly, a first semiconductor device 200 on which a predetermined integrated circuit pattern is formed is prepared. First TSVs 202 may be formed in the first semiconductor device 200, and a seed layer 204 may be formed only on the inner sidewall and the bottom surface of each of the first TSVs 202. Here, the first semiconductor device 200 may be either a wafer or a unitary semiconductor chip separated from a wafer. Furthermore, the depth of a first TSVs 202 may be from 20 μm to 100 μm, and the diameter of the first TSVs 202 may be from 10 μm to 30 μm.

Furthermore, the seed layers 204 may have either a single-layer structure or a multi-layer structure formed of metals which can easily be combined with solder, for example, metals such as Ti, Cu, Ni, and Au.

Next, as illustrated in FIG. 7, a solder ball 206 is positioned on the first TSVs 202 using a general method. Same as the previous embodiment, the first reflow operation may be selectively performed on each of the solder balls 206. At this point, the solder balls 206 are partially bonded to the respective seed layer 204 in the respective first TSVs 202, as illustrated in FIG. 8. Therefore, the partially bonded solder balls 206′ (FIG. 8) may be fixed at the entrance of the first TSVs 202. At this point, the first reflow operation may be performed at a temperature from 230° C. to 250° C., which is the range of temperatures at which the solder balls 206 begins to melt, for a time duration from about 5 seconds to about 15 seconds.

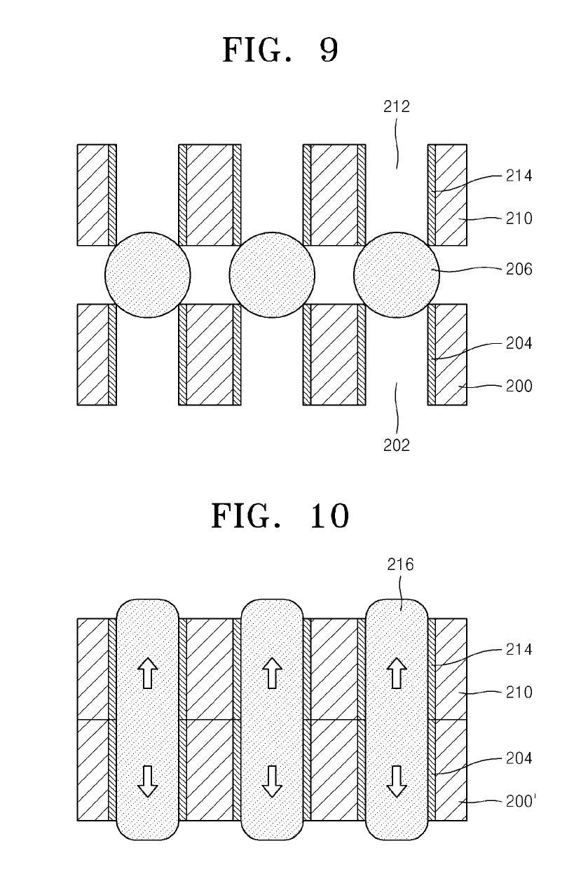

Next, as illustrated in FIG. 9, a back-lap operation to polish the bottom surface of the first semiconductor device 200 until the first semiconductor device 200 has a predetermined thickness is performed such that the first TSVs 202 completely penetrate the first semiconductor device 200. Next, a second semiconductor device 210 is positioned above the first semiconductor device 200 in which the solder balls 206 are positioned and partially bonded on the respective first TSVs 202. The back-lap operation may previously be performed on the second semiconductor device 210 such that a second TSVs 212 completely penetrate the second semiconductor device 210. Furthermore, a seed layer 214 may have been formed on the sidewall of each of the second semiconductor devices 210. The second semiconductor device 210 may be either a semiconductor device that performs the same functions as the first semiconductor device 200 or a semiconductor device that performs different functions to those of the first semiconductor device 200.

Finally, the second reflow operation is performed on the structure illustrated in FIG. 9 to melt the solder balls 206. As a result, due to capillary motion, the solder balls 206 fill the first TSVs 202 and the second TSVs 212 and forms a contact electrode 216 simultaneously. At the same time, the first and second semiconductor devices 200 and 210 are vertically interconnected due to the capillary motion.

Meanwhile, in the current embodiment, the seed layers 204 and 214 are formed only on inner sidewalls of the first and second TSVs 202 and 212 in the first and second semiconductor devices 200 and 210, respectively. Therefore, as compared to FIG. 5, a structure in which the first and second semiconductor devices 200 and 210 are interconnected via a contact electrode may be a closer interconnection between the first and second semiconductor devices 200 and 210. Therefore, according to the shapes of seed layers, bonding structures with various shapes can be fabricated. Thus, when the method is actually applied to fabricate a semiconductor device, stacked semiconductor packages with various shapes can be fabricated.

Furthermore, according to the present embodiment, the filling operation in which the contact electrode 216 is formed and the interconnecting operation in which the first and second semiconductor devices 200 and 210 are interconnected are simultaneously performed on the first and second semiconductor devices 200 and 210. Therefore, as compared to a case in which the filling operation and the interconnecting operation are performed separately, the possibility of defects, such as a void or a crack, on the interface between the first and second semiconductor devices 200 and 210 may be reduced, and thus, a decrease in yield of the completed products can be prevented.

FIGS. 11 through 14 are sectional views illustrating a method of interconnecting semiconductor devices using capillary motion, according to another embodiment of the present inventive concept.

Referring to FIGS. 11 through 14, a solder ball 306 is positioned above a first semiconductor device 300 and a back-lap operation is separately performed as in the previous embodiments. However, according to the current embodiment, a back-lap operation is performed on the first semiconductor device 300 before the solder ball 306 is positioned above the first semiconductor device 300, and then the formation of a contact electrode and interconnection of two semiconductor devices are simultaneously performed.

More particularly, the first semiconductor device 300, to which a back-lap operation is performed and first TSVs 302 completely penetrate the first semiconductor device 300, is prepared. At this point, a seed layer 304 is formed in each of the first TSVs 302, wherein the seed layer 304 may be formed on the inner sidewall of each of the first TSV 302, as also shown in FIG. 9. Next, solder balls 306 are positioned on respective ones of the first TSVs 302, as illustrated in FIG. 12. At this point, the first reflow operation may be performed on the solder balls 306, as described above.

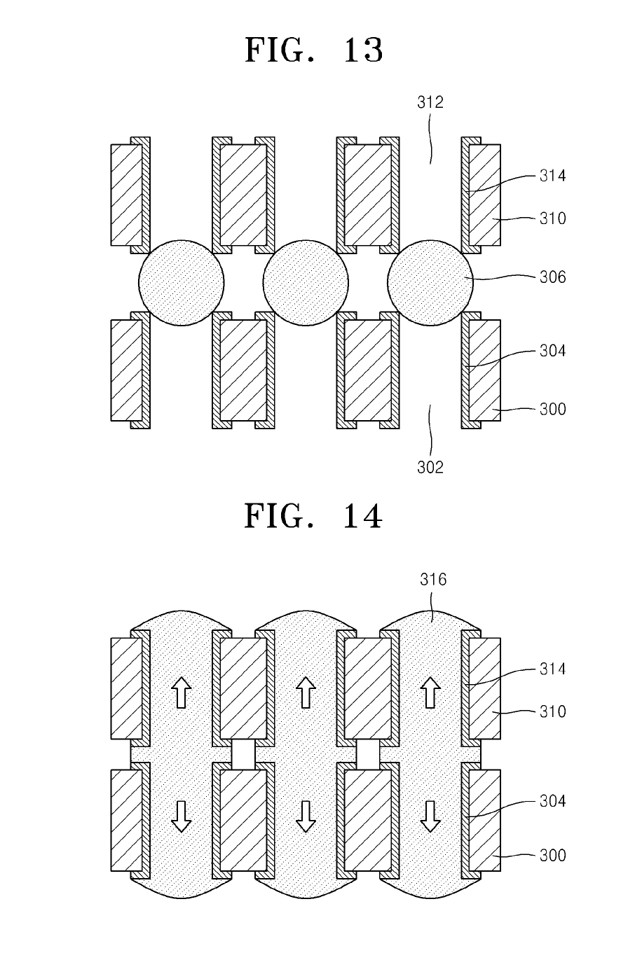

Next, as illustrated in FIG. 13, a second semiconductor device 310, which has the same structure as the first semiconductor device 300, is positioned above the first semiconductor device 300 on which the solder balls 306 are positioned. Also, as shown in FIG. 13, the semiconductor device 310 includes second TSVs 312 having a seed layer 314 formed in each of their inner sidewalls. Finally, the second reflow operation is performed so that, due to capillary motion, the solder balls 306 each form a contact electrode 316 that fills the first and second TSVs 302 and 312, and thus, the first and second semiconductor devices 300 and 310 are interconnected simultaneously.

While the present general inventive concept has been particularly shown and described with reference to exemplary embodiments thereof, it will be understood that various changes in form and details may be made therein without departing from the spirit and scope of the following claims.

What is claimed is:

1. A method of interconnecting semiconductor devices by using capillary motion, the method comprising:
preparing a first semiconductor device in which first through-silicon-vias (TSV) are formed;
positioning conductive bumps respectively on the first TSVs;
positioning a second semiconductor device, in which second TSVs are formed, above the first semiconductor device on which the conductive bumps are positioned respectively on the first TSVs; and
performing a reflow operation such that the conductive bumps fill the first and second TSVs due to capillary motion.

2. The method of claim 1, wherein the first and second semiconductor devices are semiconductor chips.

3. The method of claim 1, wherein the first and second semiconductor devices are wafers.

4. The method of claim 1, wherein a seed layer is formed in each of the first and second TSVs.

5. The method of claim 4, wherein the seed layer includes a single-layer structure formed of metals that can easily be combined with solder, metals such as Ti (titanium), Cu (copper), Ni (nickel), and Au (gold).

6. The method of claim 4, wherein the seed layer includes a multi-layer structure formed of metals that can easily be combined with solder, metals such as Ti, Cu, Ni, and Au.

7. The method of claim 4, wherein the seed layer is formed only on an inner sidewall of each of the first and second TSVs.

8. The method of claim 1, wherein a seed layer is formed on an inner sidewall and partially on top and bottom surfaces of each of the first and second TSVs.

9. The method of claim 1, further comprising:
positioning the conductive bumps on the first TSVs and performing a first reflow operation to fix the conductive bumps to the first TSVs.

10. The method of claim 9, wherein the first reflow operation is performed at a temperature from 230° C. to 250° C. for a time duration from 5 seconds to 15 seconds.

11. The method of claim 1, further comprising:
performing a back-lap operation on the first semiconductor device after positioning the conductive bumps on the first TSVs.

12. A method of interconnecting semiconductor devices by using capillary motion, the method comprising:
preparing a first semiconductor device on which a back-lap operation is performed and in which first through-silicon-vias (TSVs) are formed;
positioning solder balls respectively on the first TSVs;
positioning a second semiconductor device, in which second TSVs are formed, above the first semiconductor device on which the solder balls are positioned; and
performing a reflow operation such that the solder balls fill the first and second TSVs due to capillary motion.
